(19) United States
(12) Patent Application Publication
(10) Pub. No.: US 2023/0230851 A1
(43) Pub. Date: Jul. 20, 2023

(54) TRANSFER OF WIDE AND ULTRAWIDE BANDGAP LAYERS TO ENGINEERED SUBSTRATE

(71) Applicant: UNIVERSITY OF SOUTH CAROLINA, Columbia, SC (US)

(72) Inventors: ASIF KHAN, IRMO, SC (US); MVS CHANDRASHEKHAR, COLUMBIA, SC (US); MD DIDARUL ALAM, WEST COLUMBIA, SC (US); MIKHAIL E. GAEVSKI, MOUNT SINAI, NY (US)

(21) Appl. No.: 17/986,579

(22) Filed: Nov. 14, 2022

Related U.S. Application Data
(60) Provisional application No. 63/300,729, filed on Jan. 19, 2022.

(51) Int. Cl. H01L 21/48; H01L 21/02; H01L 21/78; H01L 23/373; H01L 29/20; H01L 29/205; H01L 29/778

(52) U.S. Cl. CPC H01L 21/4882; H01L 21/02079; H01L 21/7813; H01L 23/3736; H01L 29/2003; H01L 29/205; H01L 29/7786

(57) ABSTRACT

The present disclosure relates to use of 193-nm excimer laser-based lift-off (LLO) of Al_{0.26}Ga_{0.74}N/GaN High-electron mobility transistors (HEMTs) with thick (t>10 μm) AlN heat spreading buffer layers grown over sapphire substrates. The use of the thick AlN heat spreading layer resulted in thermal resistance (Rₜₕ) of 16 Kmm/W for as-fabricated devices on sapphire, which is lower than the value of ≈25-50 Kmm/W for standard HEMT structures on sapphire without the heat-spreaders. Soldering the LLO devices onto a copper heat sink led to a further reduction of Rₜₕ to 8 Kmm/W, a value comparable to published measurements on bulk SiC substrates. The reduction in Rₜₕ by LLO and bonding to copper led to significantly reduced self-heating and drain current droop. A drain current density as high as 0.9 A/mm was observed despite a marginal reduction of the carrier mobility (≈1800 to ≈1500 cm²/Vs). This is the highest drain current density and mobility reported to-date for LLO AlGaN/GaN HEMTs.

### PRIORITY CLAIM

The present application claims the benefit of priority of U.S. Provisional Patent Application No. 63/300,729, titled “Transfer of Wide and Ultrawide Bandgap Layers to Engineered Substrate,” filed Jan. 19, 2022, which is fully incorporated herein by reference for all purposes.

### STATEMENT REGARDING SPONSORED RESEARCH OR DEVELOPMENT

This disclosure was made with government support under W911NF-18-1-0029, awarded by ARMY/ARO; N00014-18-1-2429, awarded by ONR; and 1711322, 1810116, and 1831954, awarded by NSF ECCS. The government has certain rights in the disclosure.

### BACKGROUND OF THE PRESENTLY DISCLOSED SUBJECT MATTER

The intrinsic properties of both wide bandgap (WBG) and ultrawide bandgap (UWBG) semiconductor materials make them suitable for a wide range of other applications in High-power and radio frequency (RF) electronics, deep ultraviolet (DUV) optoelectronics, quantum electronics, and high-temperature harsh environment applications. However, the full performance of these materials cannot be achieved due to the thick substrates they are typically grown so as to ensure single crystal quality. These substrates include Si, SiC, sapphire, AlN, and Ga2O₃ among others, and the thickness is typically ˜400-500 μm. Although these thick substrates are convenient for growing and handling these semiconductors, they limit the figures-of-merits (FOMs) for device performance in the following application areas:
Baliga's FOM for power devices: These thick substrates introduce series electrical resistance.
Johnson's FOM for RF device: Parasitic capacitance from highly doped large substrates, e.g., SiC/Si has detrimental effects on WBG and UWBG RF devices.
Thermal FOM for power/thermal management: High thermal mass/resistance from very thick substrates results in a large temperature rise, which in turn limits the applicability of UWBG semiconductor power devices. Even substrate with high thermal conductivity (K) such as SiC suffers from this ^{[58,46,48]}.
DUV Optics: DUV optoelectronic devices are very sensitive to optical path length, e.g., AlN substrates are strongly absorbing in the UV, leading to low extraction efficiency in LEDs.

Thus, the removal of these thick substrates allows eliminating the above-mentioned drawbacks. However, handling thin active layers without damage is a challenge. There is currently no product that addresses this problem in the field of wide bandgap semiconductors. We propose the following approaches that have not been applied to UWBG power and RF devices. In some cases, these technologies have not been applied to DUV optics.

Presently disclosed subject matter relates to a novel laser lift-off (LLO) technique for AlN lift-off from sapphire substrates, which is highly desired for UWBG AlGaN HEMTs, which are always grown with AlN buffer layers.

### SUMMARY OF THE PRESENTLY DISCLOSED SUBJECT MATTER

Aspects and advantages of the presently disclosed subject matter will be set forth in part in the following description, or may be apparent from the description, or may be learned through practice of the presently disclosed subject matter.

Broadly speaking, the presently disclosed subject matter relates to laser-based lift-off (LLO) of high-electron mobility transistors (HEMTs). More particularly, the present disclosure is related to excimer laser lift-off of AlGaN/GaN HEMTs on thick AlN heat spreaders.

Still other aspects of the presently disclosed subject matter relate to innovations in advanced laser lift-off in GaN. For example, in some instances, presently disclosed subject matter relates to the transfer of wide and ultra-wide bandgap layers to engineered substrates.

Further, for example, we developed a novel laser lift-off (LLO) technique for AlN lift-off from sapphire substrates, which is highly desired for UWBG AlGaN HEMTs, which are always grown with AlN buffer layers.

This disclosure allows us to improve the thermal management and efficacy of power electronics devices in demanding applications that require high-current density operation such as hybrid electric vehicle (HEV) and aerospace applications by enabling us to manufacture smaller, lighter, more efficient high-power UWBG semiconductor devices in a cost-effective manner.

This technique also allows the full realization of III-nitride's potential in flexible electronics, such as power amplifiers for antenna/transmitters embedded in smartphone touchscreens, as well as in DUV optics for application areas such as COVID-19 disinfection, air treatment, and phototherapy, etc. A III-nitride compound semiconductor is formed due to the bonding of one of the group III elements, such as boron, aluminum, gallium or indium, with the group V element, nitrogen. The III-nitrides and their alloys are direct band gap semiconductors.

Further and generally speaking, this disclosure addresses the main performance/reliability problem in WBG and UWBG power devices. AlGaN/GaN HEMTs penetrated consumer electronics with first-order applications. However, the performance of the devices is currently limited by severe self-heating effects, which significantly reduce their efficacy in demanding applications that require high-current density operation. This requires an efficient heat dissipation strategy in high power handling devices employed in HEV, aircraft electronic systems, etc. Moreover, power devices are typically rated in $/Ampere from a commodities standpoint. By doubling the power handling with our LLO approach, we have effectively demonstrated how to cut the cost by 50%. In addition, improvements may be achieved through further optimization of die-attach.

Moreover, flexible devices are desired for several applications, such as biosensors, smartwatches, virtual reality (VR) and augmented reality (AR) devices, smart jackets, power amplifiers for antenna/transmitters embedded in smartphone touchscreens, etc. Removing thick substrate and transferring onto a flexible substrate with this approach can be applied to realize flexible electronics where III-nitride has not played a big role.

Laser Lift-Off (LLO) refers generally to a process where thin layers are separated from a substrate, such as polymers from glass, by use of a homogenized UV wavelength laser beam. One broad aspect of successful LLO is that the substrate be transparent to the working wavelength, and the target layer be opaque.

One basic concept behind laser lift-off generally is the difference in absorption of the laser light by one layer, typically a host substrate, and the filmstack being separated. For laser lift-off generally, a laser light source is projected through a transparent material and is absorbed in an adjacent material on the backside, such as GaN on sapphire. Confined plasma at the interface results in lift-off or separation of the materials. In the case of LEDs for example, short wavelength laser light passes through the sapphire and ablates the interface when it couples with the GaN, thereby releasing the two materials.

In the case of monolithic advanced lift-off in GaN, shorter wavelengths/higher energy photons are better absorbed, resulting in shallower optical penetration depth in certain materials such as GaN. UV pulses can be used for separation of thin film semiconductor materials when the heat penetration depth needs to be minimal.

Generally, an excimer laser is a form of ultraviolet laser sometimes used in the production of microelectronic devices, semiconductor-based integrated circuits, eye surgery, and micromachining. Aluminum nitride (AlN) is a technical ceramic material that features a combination of very high thermal conductivity and favorable electrical insulation properties. Such combination makes aluminum nitride suitable for use in power and microelectronics applications, for example, used as a circuit carrier (substrate) in semiconductors or as a heat-sink in LED lighting technology or high-power electronics. III nitride materials generally comprise AlN, GaN, InN, and their solid solutions.

The presently disclosed subject matter provides the following advantages:
1—Significantly reduces thermal resistance which leads to reduced self-heating and drain current droop in WBG and UWBG power devices. By doubling the power handling with our lift-off approach, we have effectively demonstrated how to cut the cost by 50%.
2—Reduces the cost of devices grown on high thermal conductivity SiC or bulk AlN substrates as the cost of these substrates are ˜3 to 10-times that of sapphire substrates while providing similar device performance metrics.
3—Our double transfer approach eliminates the need for a final polishing step, which is essential for smart-cut technology.
4—This technique enables the realization of the full potential of III-nitride in flexible electronics.

The presently disclosed subject matter could be useful to companies that manufacture high-power semiconductor devices seeking an alternative material for SiC as substrate and that can reduce the cost significantly while providing similar performance metrics of devices. That list of companies could include developers of specialized devices and sensors for health care and military applications.

It is to be understood from the complete disclosure herewith that the presently disclosed subject matter equally relates to both apparatus and corresponding and related methodology and/or to devices made with such methods and methodology.

One presently disclosed exemplary methodology preferably relates to a method for transferring wide and ultrawide bandgap (WBG and UWBG) layers to an engineered substrate, comprising performing laser-based lift-off (LLO) on high-electron mobility transistors (HEMTs) with AlN heat spreading buffer layers grown over sapphire substrate material, to remove the sapphire substrate material; and applying a carrier substrate to the heat spreading buffer layers using a bonding agent, to collectively form an engineered substrate.

Another presently disclosed exemplary method relates to a double transfer method for fabricating WBG and UWBG semiconductor devices without requiring a final polishing step. Such method preferably may comprise forming AlGaN/GaN HEMTs on a layer of AlN heat spreaders having a thickness of at least 10 μm, grown over sapphire substrate materials; applying excimer laser lift-off to remove the sapphire substrate materials to expose the layer of AlN heat spreaders; and using a bonding agent to apply a heat sink layer to the exposed layer of AlN heat spreaders. Per such method, first transferring off the sapphire substrate materials and subsequently transferring on a heat sink layer results in engineered formation of WBG and UWBG power devices.

Yet another presently disclosed exemplary embodiment relates to methodology for forming a layered substrate, comprising performing laser-based lift-off (LLO) on AlGaN high-electron mobility transistors (HEMTs) with ceramic heat-spreading buffer layers having relatively high-thermal conductivity, and grown over sapphire substrate material, to remove the sapphire substrate material; and applying a copper heat sink to the ceramic heat spreading buffer layers using a bonding agent, to collectively form an engineered layered substrate.

Other example aspects of the present disclosure are directed to systems, apparatus, tangible, non-transitory computer-readable media, user interfaces, memory devices, and electronic smart devices or the like. To implement methodology and technology herewith, one or more processors may be provided, programmed to perform the steps and functions as called for by the presently disclosed subject matter, as will be understood by those of ordinary skill in the art.

Additional objects and advantages of the presently disclosed subject matter are set forth in, or will be apparent to, those of ordinary skill in the art from the detailed description herein. Also, it should be further appreciated that modifications and variations to the specifically illustrated, referred and discussed features, elements, and steps hereof may be practiced in various embodiments, uses, and practices of the presently disclosed subject matter without departing from the spirit and scope of the subject matter. Variations may include, but are not limited to, substitution of equivalent means, features, or steps for those illustrated, referenced, or discussed, and the functional, operational, or positional reversal of various parts, features, steps, or the like.

Still further, it is to be understood that different embodiments, as well as different presently preferred embodiments, of the presently disclosed subject matter may include various combinations or configurations of presently disclosed features, steps, or elements, or their equivalents (including combinations of features, parts, or steps or configurations thereof not expressly shown in the figures or stated in the detailed description of such figures). Additional embodiments of the presently disclosed subject matter, not necessarily expressed in the summarized section, may include and incorporate various combinations of aspects of features, components, or steps referenced in the summarized objects above, and/or other features, components, or steps as otherwise discussed in this application. Those of ordinary skill in the art will better appreciate the features and aspects of such embodiments, and others, upon review of the remainder of the specification, and will appreciate that the presently disclosed subject matter applies equally to corresponding methodologies as associated with practice of any of the present exemplary devices, and vice versa.

### BRIEF DESCRIPTION OF THE FIGURES

A full and enabling disclosure of the presently disclosed subject matter, including the best mode thereof, directed to one of ordinary skill in the art, is set forth in the specification, which makes reference to the appended Figures, in which:

FIGS. 1A though 1F schematically represent respective aspects of presently disclosed laser lift-off (LLO) technology for AlN lift-off from substrates;

FIG. 2A graphically shows micro-Raman spectra of the Al_{0.26}Ga_{0.74}N/GaN HEMT before and after presently disclosed LLO technology;

FIG. 2B graphically illustrates a comparison of as-fabricated data versus after presently disclosed LLO technology;

FIGS. 3A and 3B respectively illustrate graphically capacitance versus V_{GS} before and after presently disclosed LLO technology, at different frequencies;

FIGS. 4A and 4B respectively show graphically the output characteristics of the HEMT before and after presently disclosed LLO;

FIG. 4C graphically illustrates Power Density both before (data set to the left on the graph) and after (data set to the right on the graph) presently disclosed LLO;

FIG. 5A graphically illustrates gₘ versus V_{GS}, where x-intercept gives V_{T}, and it shifted negative by 1V after presently disclosed LLO versus results for the as-fabricated device;

FIG. 5B graphically illustrates the breakdown voltage characteristics of the Al_{0.26}Ga_{0.74}N/GaN HEMT before and after presently disclosed LLO with gate—drain spacing, L_{GD}=3 μm;

FIGS. 6A and 6B respectively illustrate GaN E₂ (High) Raman strain mapping as-fabricated (FIG. 6A), and in presently disclosed LLO GaN HEMT (FIG. 6B);

FIGS. 6C and 6D respectively illustrate AlN E₂ (High) Raman strain mapping as-fabricated (FIG. 6C), and in presently disclosed LLO GaN HEMT (FIG. 6D);

FIG. 7A graphically illustrates the a and c lattice constants of different epitaxial films, as well as a presently disclosed sample before and after presently disclosed LLO determined by HRXRD measurements;

FIG. 7B graphically displays the room temperature Raman shift vs corresponding residual stress for both E₂ (High) and A₁ (Lo) modes;

FIGS. 8A and 8B respectively show graphically various output characteristics of the HEMT under certain conditions before and after presently disclosed LLO; and

FIGS. 9A and 9B respectively illustrate graphically the I_{DS}-V_{GS} transfer curves before and after presently disclosed LLO.

Repeat use of reference characters in the present specification and figures is intended to represent the same or analogous features or elements or steps of the presently disclosed subject matter.

### DETAILED DESCRIPTION OF THE PRESENTLY DISCLOSED SUBJECT MATTER

It is to be understood by one of ordinary skill in the art that the present disclosure is a description of exemplary embodiments only and is not intended as limiting the broader aspects of the disclosed subject matter. Each example is provided by way of explanation of the presently disclosed subject matter, not limitation of the presently disclosed subject matter. In fact, it will be apparent to those skilled in the art that various modifications and variations can be made in the presently disclosed subject matter without departing from the scope or spirit of the presently disclosed subject matter. For instance, features illustrated or described as part of one embodiment can be used with another embodiment to yield a still further embodiment. Thus, it is intended that the presently disclosed subject matter covers such modifications and variations as come within the scope of the appended claims and their equivalents.

The present disclosure is generally directed to laser-based lift-off (LLO) of High-electron mobility transistors (HEMTs). More particularly, the present disclosure is related to excimer laser lift-off of AlGaN/GaN HEMTs on thick AlN heat spreaders.

Further, the present disclosure in some instances relates to the use of 193-nm excimer laser-based lift-off (LLO) of Al_{0.26}Ga_{0.74}N/GaN high-electron mobility transistors (HEMTs) with thick (t>10 μm) AlN heat spreading buffer layers grown over sapphire substrates. The use of the thick AlN heat spreading layer resulted in thermal resistance (Rₜₕ) of 16 Kmm/W for as-fabricated devices on sapphire, which is lower than the value of ≈25-50 Kmm/W for standard HEMT structures on sapphire without the heat-spreaders. Soldering the LLO devices onto a copper heat sink led to a further reduction of Rₜₕ to 8 Kmm/W, a value comparable to published measurements on bulk SiC substrates. The reduction in Rₜₕ by LLO and bonding to copper led to significantly reduced self-heating and drain current droop. A drain current density as high as 0.9 A/mm was observed despite a marginal reduction of the carrier mobility (≈1800 to ≈1500 cm²/Vs). This is the highest drain current density and mobility reported to-date for LLO AlGaN/GaN HEMTs.

AlGaN/GaN High-electron mobility transistors (HEMTs) have come a long way since their initial demonstration in 1993 and are desired for a multitude of applications in high-frequency and high-temperature power electronics.^{[1-8]} Recently, AlGaN/GaN HEMTs penetrated the consumer electronics with first-order applications.^{[9,10]} However, the performance of the devices is currently limited by severe self-heating effects that significantly reduce their efficacy in demanding applications that require high current density operation. One strategy to reduce the self-heating effects of GaN-based HEMTs is to use high thermal conductivity SiC or bulk AlN substrates. However, the cost of these substrates is ≈3-10 times that of sapphire substrates.^{[11]} Hence, strategies to improve the thermal management of the devices are highly desired for the full realization of III-nitride-based device's potential in power electronics.

One promising approach for better thermal management of HEMTs on sapphire substrates is the LLO and bonding to a substrate with higher thermal conductivity. This approach has been used for visible InGaN and ultraviolet (UV) AlGaN LEDs^{[12-19]} and HEMTs (Table 1).^{[20-26]} The laser lifted-off devices are typically mounted on an Si, AlN, or a metallic heat sink, such as copper, commonly used in power electronics.^{[27,28]} This leads to further challenges in assuring bonding with low thermal impedance and preserving the structural integrity of the III-nitride epi-layers. If the thickness of the III-nitride layer is small compared to the solder thickness of 10-50 μm, it may wrinkle, crack, and be damaged during the solder reflow. However, too thick an epilayer can also introduce more thermal resistance. Ultraviolet LEDs with typical epilayer thicknesses of 2-3 μm when flip-chipped by LLO^{[15]} are also susceptible to cracking. Due to this damage, LLO HEMTs typically are not soldered directly to highly thermally conductive metallic heat sinks.^{[21-25]}

| Ref. laser | Bonding agent | Carrier substrate | | | | |
|---|---|---|---|---|---|---|
| λ (nm) buffer | (thermal | (thermal conductivity, | | | | |
| layer with | conductivity, | W/mK) | Mobility (cm²/V s) | | Sheet resistance (Ω/sq) | |
| thickness (μm) | W/mK) | (thickness, mm) | AF | LL | AF | LLO |
| This work 193 | In—Pb solder | Copper (~386 [symbol] ) | ~1800 (V_{T} = −8.5 V) | ~1500 | ~310 (TLM) | ~375 (TLM) |
| AlN (16) | (~41) [symbol] | (~2) | | (V_{T} = −9.5 V) | | |
| Wang et al.²⁰ | None | Glass (~0.8 [symbol] ) | ~1520 (Hall) ~55 | ~44 | ~484 (Hall) | ~1.6 × 10⁴ |
| 193 GaN (2) | | (~1 est.) | (V_{T} = −3.4 V) | (V_{T} = −3.2 V) | ~1.1 × 10⁴ | |
| Das et al.²¹ | glue | AlN (~180²¹) | ~102 (V_{T} = −5 V) | ~86 | ~5.1 × 10³ | ~5.7 × 10¹³ |
| 355 GaN (4.3) | | (~0.4 est.) | | (V_{T} = −5.2 V) | | |
| Chan et al. [symbol] | Silver paint (~9.1 [symbol] ) | Si (~150 [symbol] ) | ~1000 (Hall) | ~1000 est. (Hall) | ~670 est. | Not reported |
| 248 GaN (2.5) | | (~0.5 est.) | | | | |
| [symbol] et al. [symbol] 355 | Au/In/Au | Si (~150) | ~145 (V_{T} = −3.5 V [symbol] | ~96 (V_{T} = −4 V) | ~5.7 × 10³ | ~7.3 × 10³ |
| GaN (2.6) | direct bond | (~0.5 est.) | | | | |

| Ref. laser | Bonding agent | Carrier substrate | | |
|---|---|---|---|---|
| λ (nm) buffer | (thermal | (thermal conductivity, | Sheet carrier concentration | |
| layer with | conductivity, | W/mK) | (cm⁻²) | |
| thickness (μm) | W/mK) | (thickness, mm) | AF | LLO |
| This work 193 | In—Pb solder | Copper (~386 [symbol] ) | ~1 × 10¹³ | ~1 × 10¹³ |
| AlN (16) | (~41) [symbol] | (~2) | | |
| Wang et al.²⁰ | None | Glass (~0.8 [symbol] ) | ~8.5 × 10¹² | ~8.8 × 10¹² |
| 193 GaN (2) | | (~1 est.) | (Hall) | |
| Das et al.²¹ | glue | AlN (~180²¹) | ~1.2 × 10¹² | ~1.2 × 10¹² |
| 355 GaN (4.3) | | (~0.4 est.) | | |
| Chan et al. [symbol] | Silver paint (~9.1 [symbol] ) | Si (~150 [symbol] ) | ~9.3 × 10¹² | Not reported |
| 248 GaN (2.5) | | (~0.5 est.) | (Hall) | |
| [symbol] et al. [symbol] 355 | Au/In/Au | Si (~150) | ~8 × 10¹² | ~9 × 10¹² |
| GaN (2.6) | direct bond | (~0.5 est.) | | |

[symbol]

No field effect mobility was able to be extracted due to unavailability of device dimensions. [symbol]
indicates data missing or illegible when filed

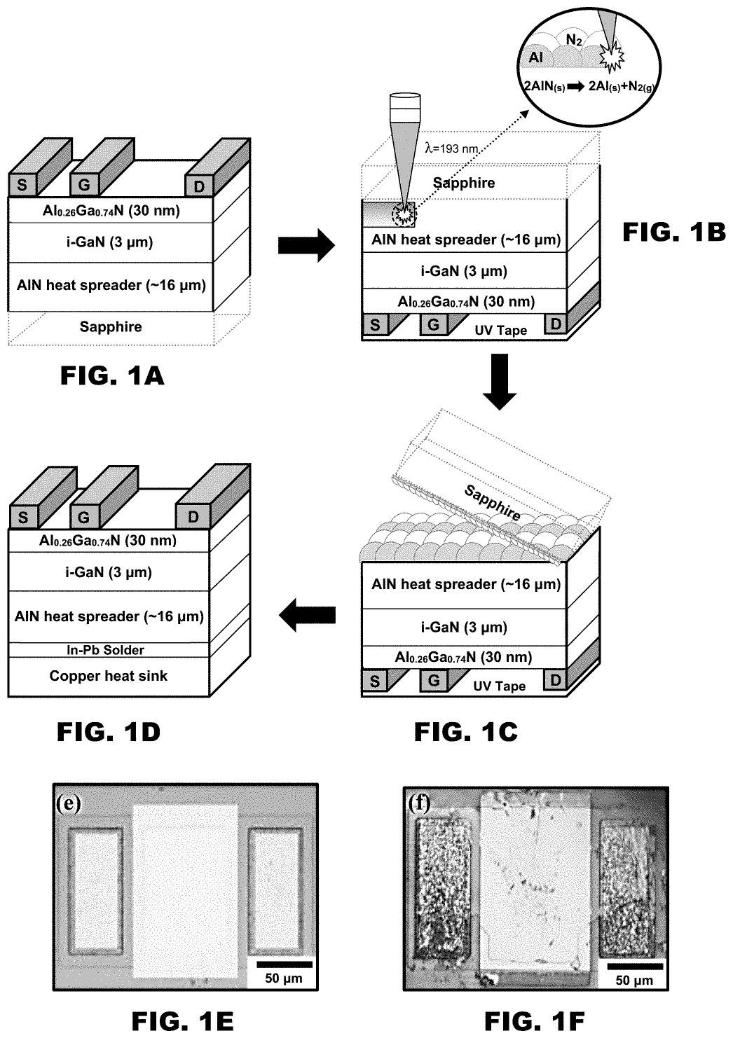

Further, for example, we developed a novel laser lift-off (LLO) technique for AlN lift-off from sapphire substrates, which is highly desired for UWBG AlGaN HEMTs which are always grown with AlN buffer layers. The general approach is shown in present FIGS. 1A-1F. A 193-nm ArF excimer laser was used to LLO Al_{0.26}Ga_{0.74}N/GaN HEMT with >10 μm thick AlN templates from sapphire substrate and transferred onto an engineered copper heat sink with solder. Obtaining high fluences at these extreme wavelengths is challenging due to the Low efficiency of excimer lasers. Further, scaling of III-nitride technology from metamorphic GaN to pseudomorphic UWBG AlxGa₁₋ₓN (x>0.6) for power devices on AlN will continue to require laser wavelengths <<250 nm, the band-edge wavelength for AlxGa₁₋ₓN (x ˜0.65). The MOCVD grown AlGaN/GaN heterostructures on a c-plane sapphire were started by a 2-μm AlN seed layer followed by the selective area growth (SAG) of 14-μm thick AlN in 1×1 mm² window openings in a SiO₂ masking layer. The SiO₂ mask was then etched off using HF, and the first 2-μm thick AlN seed layer was also etched down by inductively coupled plasma (ICP), leaving a template with fully disconnected 16 μm thick 1×1 mm² blocks of AlN on the sapphire substrate.

Appropriately sized trenches are required to remove the generated N₂ gas during laser exposure. In our studies, ˜1 mm² dimensions were suitable to be large enough for practical applications and for scaling (laser spot size ˜1 mm²) while being small enough to provide sufficient area for removal of N₂ gas generated during the excimer laser decomposition of UWBG III-N. The HEMT epilayers were then grown on these SAG AlN template, which consists of a 3 μm undoped GaN channel layer and a 30 nm delta-doped Al_{0.26}Ga_{0.74}N layer with a 1 nm AlN spacer in between. Ohmic contact metal stack Ti/Al/Ti/Au (150/700/300/500 Å) was e-beam evaporated and annealed for 30 seconds at 950° C. under N₂ followed by gate-stack Ni/Au (1000/2000 Å) metallization. The metal contact side of the sample was bonded to a UV tape, and the sapphire was removed by LLO. The lifted-off AlN surface was then cleaned with 1:1 dilute HCl and Cl₂/Ar ICP. The lifted-off surface was bonded to a copper heat sink substrate using In—Pb solder by thermocompression bonding, and the UV tape was removed. The In—Pb solder temperature (˜175° C.) is low enough to be compatible with flexible electronics. The incorporation of thick AlN heat spreading buffer layer led to a thermal resistance (Rₜₕ) of ˜16 K-mm/W for as-fabricated devices on sapphire, which decreased further down to ˜8 K-mm/W, comparable to published measurements on SiC substrates, after transferring the devices onto a copper heat sink due to the high intrinsic thermal conductivity of AlN and removal of large series Rₜₕ of the sapphire substrate. Self-heating induced current droop in as-fabricated HEMTs on sapphire is significantly reduced after transfer onto copper heat sink. Moreover, the intermediary AlN layer provided physical integrity during the transfer preventing damage.

The mechanical transfer of WBG and UWBG active layers involves using 2D materials such as boron, nitride, graphene, MoS₂ as a sacrificial release layer. This technique allows the realization of devices on large, flexible, and affordable foreign substrates on which direct growth of nitride semiconductors of sufficient quality is problematic. This technique has been used with limited success for LEDs ^{[59,60,61,62]} and could be useful for power electronics as well. Depending on the application, engineered substrates are required, e.g., Gorilla® glass for smartphones, polyethylene terephthalate (PET) for flexible electronics.

This technique is used to transfer very fine layers of crystalline materials from a donor substrate onto a mechanical support using the Smart-Cut™ technology (Soitec® patented) and has been used for Johnson's FOM improvements in silicon ^{[63,64,65]}. This approach has not been applied to III-nitrides but could be applicable to AlN substrates leading to a transformative reduction in cost in UWBG AlGaN devices, as multiple engineered High-quality AlN templates can be produced from a single wafer. Our double transfer approach eliminates the need for a final polishing step which is essential for smart-cut technology ^{[Alam et. al (accepted)]}.

For effective soldering to copper heat sink, Ill-nitride epilayers >10 μm thick are required. We recently demonstrated the growth of such thick ultra-wide bandgap (UWBG) AlN layers on sapphire substrates with a room temperature thermal conductivity 320 W/m-K.^{[29,30]} This is much higher than the measured thermal conductivity values for GaN.^{[31-33]} These thick AlN/sapphire templates, therefore, not only are a suitable high-thermal conductivity platform for AlGaN/GaN HEMTs but can also provide protection during the soldering of lifted-off devices to copper heat sink. However, it is more difficult to release AlN than GaN from the sapphire substrate because of its hardness and higher melting temperature.^{[15]} It also requires a high-fluence short wavelength deep ultraviolet (DUV) λ=193 nm excimer laser. The hardness and the high-laser fluence lift-off invariably lead to excessive layer cracking. Developing LLO techniques for AlN lift-off from sapphire substrates is also highly desired for UWBG AlₓGa₁₋ₓN (x>0.6) HEMTs, which are always grown with AlN buffer layers. Thus, many previously demonstrated LLO approaches (Table 1) for AlGaN/GaN HEMTs are not applicable to emerging UWBG IIIN devices.^{[34-36]}

In this disclosure, we demonstrate the LLO of AlGaN/GaN HEMTs that were fabricated with >10 μm-thick high-quality AlN buffer layers on sapphire substrates. The lifted-off layers were then soldered to copper heat sink to improve their capability to operate at high-drain currents without a thermal droop attributed to self-heating.^{[37]} We show that the thermal performance is improved substantially and is like that of devices on bulk SiC substrates, the current gold-standard in heat sinks.

The AlGaN/GaN heterostructures used in this study were grown on c-plane sapphire by metalorganic chemical vapor deposition (MOCVD). A 2-μm AlN seed layer was first grown followed by the selective area growth (SAG) of 14 μm-thick AlN in 1×1 mm² window openings in a SiO₂ masking layer. The SiO₂ mask was then etched off using HF, and the first 2 μm-thick AlN seed layer was also etched down by inductively coupled plasma (ICP), leaving a template with fully disconnected 16 μm-thick 1×1 mm² blocks of AlN on the sapphire substrate. HEMT epilayers were then grown on these SAG AlN templates by MOCVD, with a 3 μm undoped GaN channel layer and a 30 nm delta doped Al_{0.26}Ga_{0.74}N layer with a 1 nm AlN spacer in between. Delta doping was done by sandwiching a 10 nm Si-doped Al_{0.26}Ga_{0.74}N layer between two undoped 10 nm Al_{0.26}Ga_{0.74}N layers. Delta doping separates the dopants from the AlGaN/GaN 2 DEG interface enabling higher sheet carrier concentration (nₛ), while minimizing carrier-impurity scattering that provides enhanced carrier mobility at high nₛ.^{[38]} These effects lead to an overall lowering of the sheet resistance. The device source/drain ohmic contact metal stack Ti/Al/Ti/Au (150/700/300/500 Å) was e-beam evaporated and annealed for 30 s at 950° C. under N₂. This was followed by the gate-stack Ni/Au (1000/2000 Å) metallization. Source-to-drain spacing was 6 μm, with a gate length of ≈2 μm.

For the LLO process, the epitaxial side of the processed sample was bonded to UV tape, and a 193-nm excimer laser fluence of ≈1 J/cm² was used. This yielded HEMT devices with 16 μm-thick AlN heat spreading layers. The lifted-off surface was etched with 1:1 dilute HCl and Cl₂/Ar ICP to remove the damaged AlN layer. The sample was then transferred to copper using thermocompression bonding. The In—Pb solder temperature (≈175° C.) ^{[39]} is low enough to be compatible with flexible electronics. This procedure is schematically represented in FIGS. 1A-1F. The HEMTs before and after LLO are also shown in FIGS. 1A-1F. The output and transfer characteristics of the HEMT before and after LLO were measured using a parameter analyzer, while the capacitance-voltage (C-V) measurements were done using an LCR meter. Micro-Raman measurements were done at 473 nm. High-resolution x-ray diffractometry (HRXRD) was done using a triple-axis diffractometer at a wavelength λ=0.154 nm.

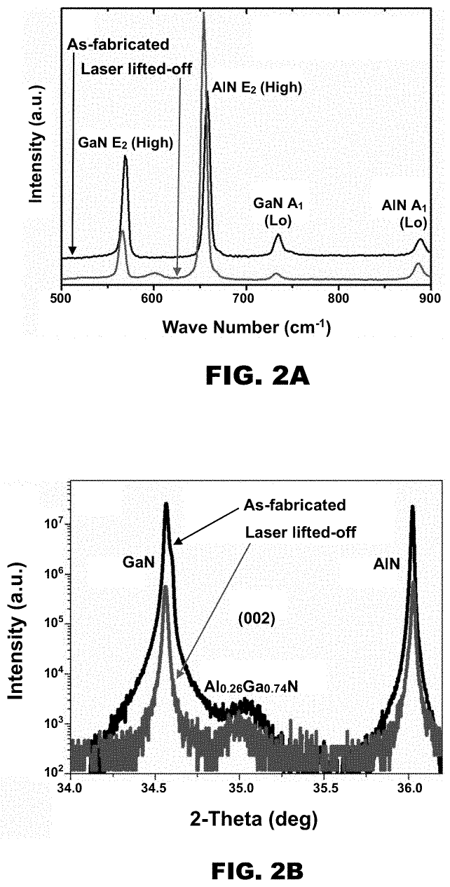

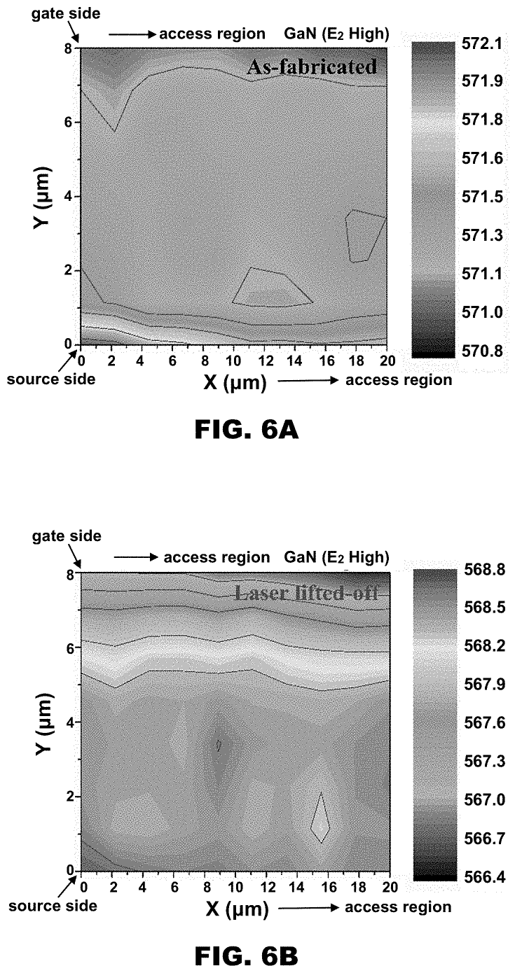

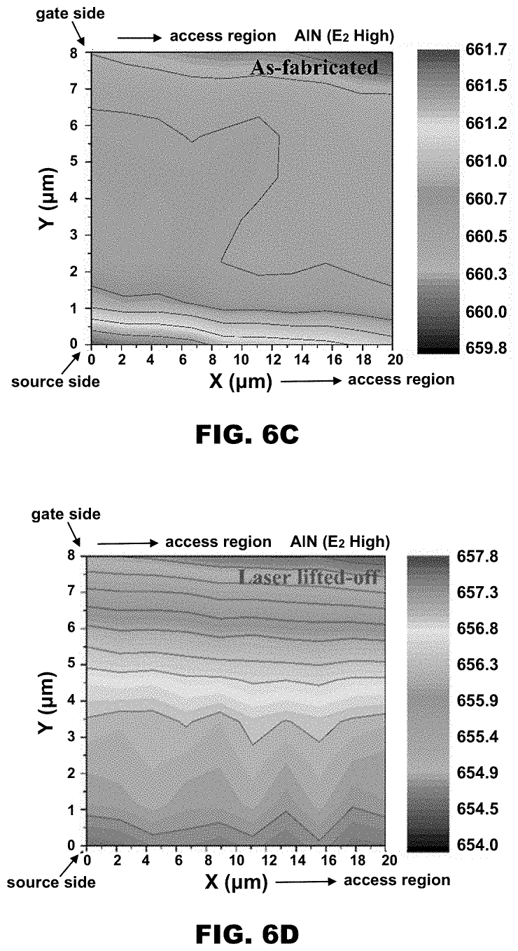

FIG. 2A shows the micro-Raman spectra of the Al_{0.26}Ga_{0.74}N/GaN HEMT before and after LLO. The E₂ (High) peaks are only sensitive to strain, unlike the A₁ (Lo) peaks, which are also sensitive to free carriers.^{[40,41]} The E₂ (High) phonon line width of the GaN channel layer, a measure of the crystalline quality, remained the same (≈7 cm⁻¹) before and after LLO.^{[40]} Both AlN and GaN E₂ (High) phonons show 2.8 cm⁻¹ red-shift after LLO, indicating strain relief in both the AlN buffer and GaN channel layers, consistent with spatial Raman maps (FIGS. 6A-6D). This red-shift corresponds to a relief of compressive biaxial stress change −0.8 GPa calculated using a stress conversion coefficient −3.09+/−0.41 cm⁻¹ GPa⁻¹.^{[42]}

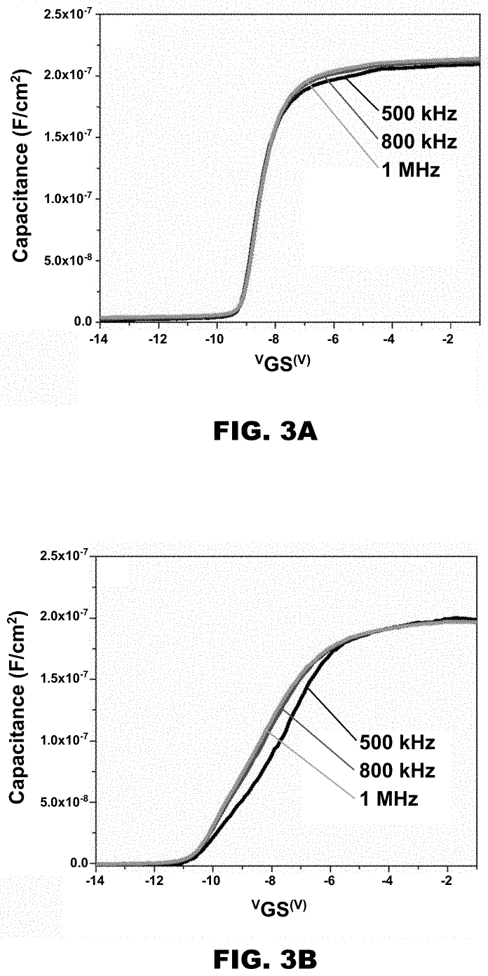

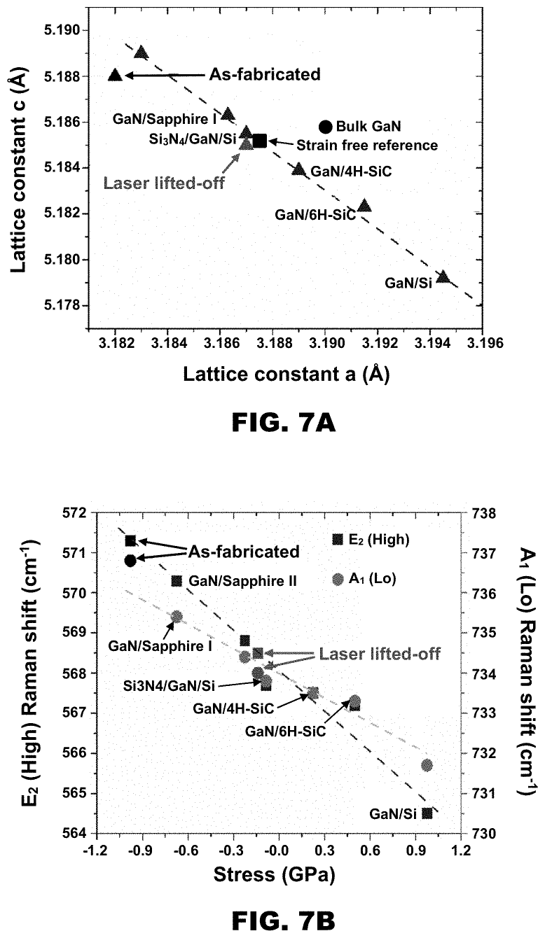

This strain relaxation is supported by HRXRD (FIG. 2B), as demonstrated by the decrease in lattice constants from c=5.1879−5.1844 Å, while it increased from a=3.1813−3.1869 Å after LLO. Based on the lattice constants from HRXRD, biaxial strain εₐ=1.6×10⁻³ was extracted^{[42]} corresponding to a stress relief of ≈0.8 GPa (FIGS. 7A and 7B), which is in excellent agreement with Raman. The relative biaxial strain of the barrier layer is preserved after LLO, as shown in FIG. 2B, by HRXRD and by the nₛ measured from frequency dependent C-V (FIGS. 3A and 3B). The nₛ before and after LLO is calculated using the following equation was ≈1×10¹³ cm⁻²,^{[36]} indicating that the epitaxial registry of the AlGaN/GaN junction is preserved,

$${qn}_{s} = {\int }_{{V}_{T}}^{0} {C}_{G 1} ( {V}_{GS} ) {dV}_{GS} , \qquad ( 1 )$$

where q is the electron charge, V_{T} is the threshold voltage, C_{G1} is the gate capacitance per unit area; and V_{GS} is the gate-source voltage.

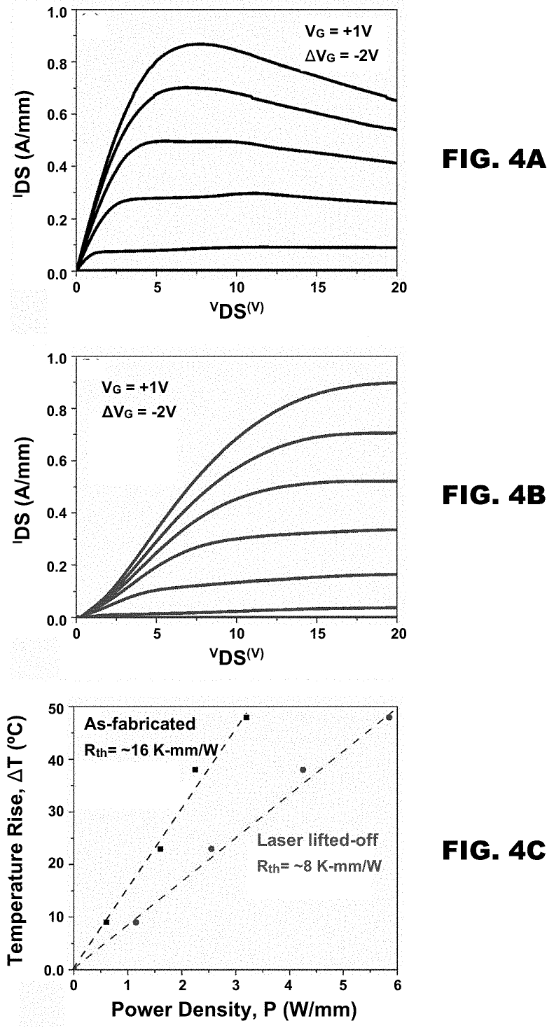

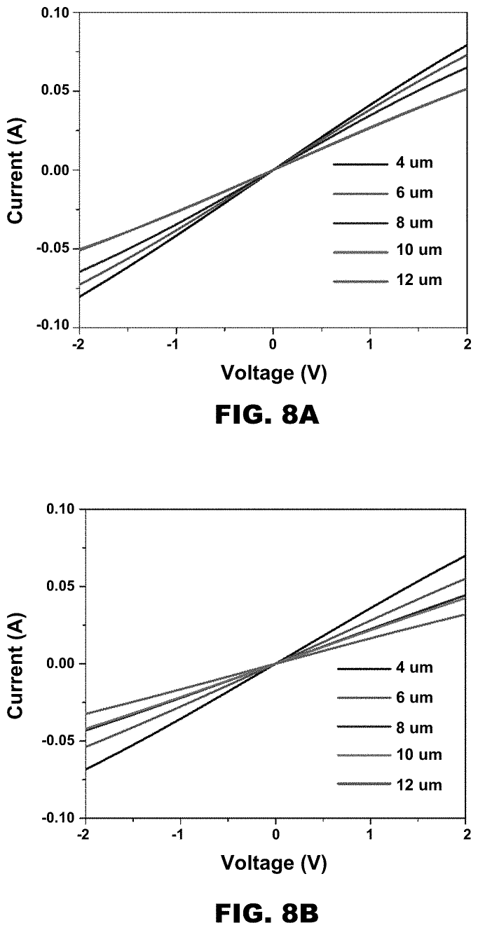

FIGS. 4A-4C show the output characteristics of the HEMT before and after LLO. The peak currents remained nearly the same as did R_{C}=0.66 Ωmm before LLO to 0.73 Ωmm after LLO (FIGS. 8A and 8B). This increase in R_{C} is most likely due to physical damage from transfer to and off the UV-tape (FIG. 1F), leading to peeling of the Ti/Au pad metals. Improved metal deposition at higher vacuum with a less adhesive transfer tape may reduce this damage, although post-transfer pad formation could also solve this R_{C} increase. Before LLO, a reduction in drain current (I_{DS}) is observed in the saturation region with increasing drain voltage (V_{DS}) due to Joule heating, commonly known as self-heating^{[37]} or thermal droop (FIG. 4A), that is significantly reduced in the LLO sample (FIG. 4B). The distance from the heat source (HEMT channel) to the heat sink is now reduced from ≈400 μm of sapphire (k≈34.6W/mK)^{[43]} down to ≈16 μm of AlN (k≈320 W/mK), eliminating a major source of Rₜₕ.^{[37]}

Rₜₕ was measured using thermochromic paint that changes its color for a certain temperature under steady state electrical power. From FIG. 4C, we calculated the Rₜₕ by: ^{[44]}

ΔT=RₜₕP, (2)

where ΔT is the channel temperature rise and P is the applied power.

The as-fabricated devices on sapphire show Rₜₕ of ≈16K mm/W, which is lower than the typical 25-50K mm/W ^{[44-47]} seen in GaN, HEMTs grown directly on sapphire. This lower Rₜₕ is attributed to the better heat spreading in the ˜16 μm-thick AlN due to its high intrinsic thermal conductivity.^{[29,30]} AlN layers <6 μm-thick showed ≈½ the thermal conductivity compared to the thicker films, leading to less effective heat removal attributed to poorer AlN quality at the sapphire/AlN interface.^{[29]} After LLO and soldering to the copper heat sink, Rₜₕ is ≈8K mm/W, which is comparable to or less than the 10K mm/W for SiC substrates^{[45,46,48]} using steady state techniques. The remaining Rₜₕ after sapphire removal and transfer onto copper heat sink is likely dominated by the poor thermal conductivity of In—Pb die-attach solder [≈41 W/mK ^{[49]} compared to the excellent thermal conductivities of AlN (≈320 W/mK) ^{[29-30]} and copper (≈386 W/mK). ^{[50]}

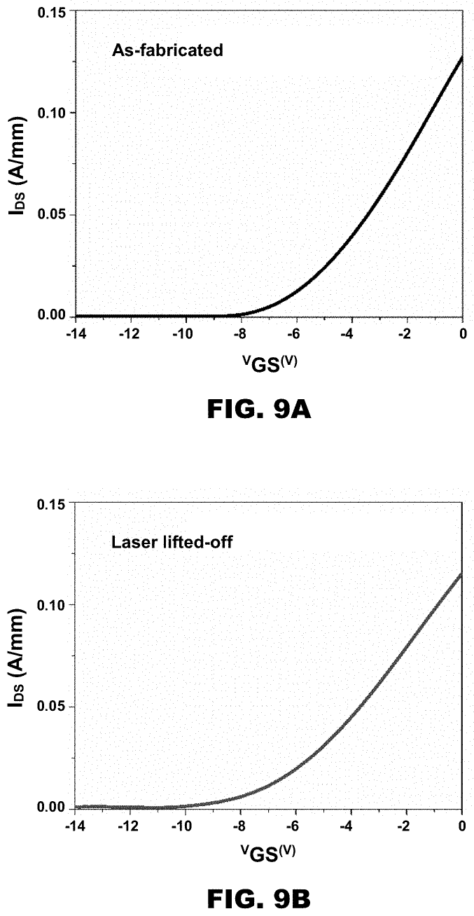

The carrier mobility (μₙ) is extracted from the I_{DS}-V_{GS} transfer curves (FIGS. 9A and 9B) using:^{[51]}

$${g}_{m} = \frac{\partial {I}_{DS}}{\partial {V}_{GS}} = {μ}_{n} {C}_{G 1} \frac{W}{L} ( {V}_{GS} - {V}_{T} ) , \qquad ( 3 )$$

where gₘ is the transconductance, L is the gate-length, and W is the width.

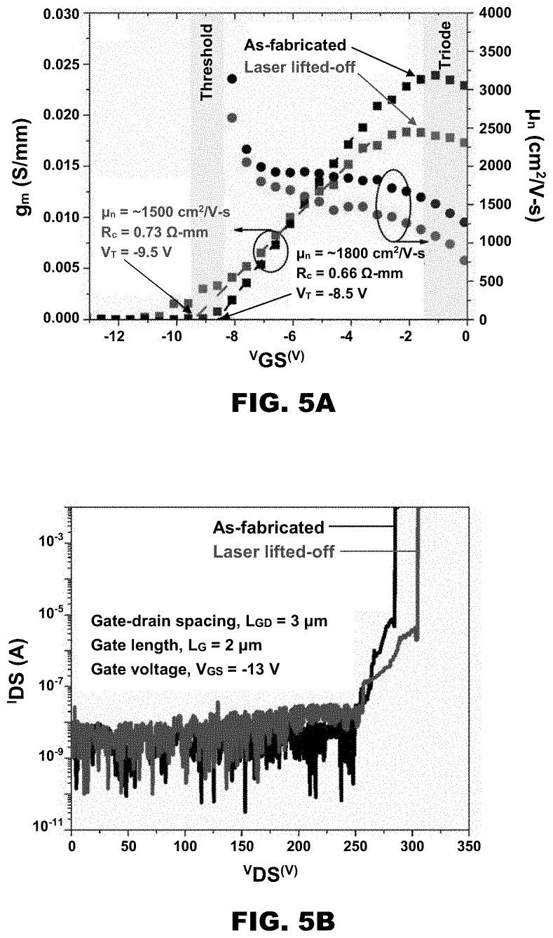

FIG. 5A shows gₘ vs V_{GS}, where x-intercept gives V_{T}, and it shifted negative by 1 V after LLO. From FIG. 5A, the μₙ in 2D-channel is found to be ≈1800 cm²/Vs for the as-fabricated device, while it decreased to ≈1500 cm²/Vs after LLO. This μₙ is extracted at V_{GS}=−5.1 V>>V_{T} to ensure the applicability of Eq. (3), while it is much lower than the maximum V_{GS}=+1 V to minimize the influence of self-heating at high current levels. The lowered mobility is attributed to the dispersion seen in C-V, indicative of higher trap densities introduced by partial strain relaxation after LLO.^{[52-55]} The μₙ is in excellent agreement with the sheet resistance from TLM (Table 1), with the TLM sheet resistance ≈10% lower than the transistor measurements.

FIG. 5B shows the breakdown voltage characteristics of the Al_{0.26}Ga0.74N/GaN HEMT before and after LLO with gate-drain spacing, L_{GD}=3 μm. The breakdown voltages (V_{BR,OFF}) of the devices were measured at OFF-state conditions (Vₜ>>VGS=−13 V) without junction edge termination. The results show V_{BR,OFF}=≈300 V, corresponding to breakdown field, E_{BR,OFF}=≈1 MV cm⁻¹ for both as-fabricated and LLO devices. Higher V_{BR,OFF} may be achievable by proper junction edge termination, such as field plate extensions on the gate, along with optimized surface passivation. Nevertheless, the relative insensitivity of V_{BR,OFF} to the LLO process underscores its viability in high voltage applications.

LLO of Al_{0.26}Ga_{0.74}N/GaN HEMT with >10 μm-thick AlN templates from sapphire substrate was performed by a 193-nm ArF excimer laser and transferred onto a copper heat sink bonded by In—Pb solder. Incorporating a thick AlN heat spreading buffer layer instead of GaN led to a Rₜₕ of ≈16K mm/W for as-fabricated devices on sapphire, which decreased further down to ≈8 Kmm/W, comparable to published measurements on SiC substrates, after transferring the devices onto a copper heat sink. This is due to improved heat spreading in the thick AlN buffer with high intrinsic thermal conductivity and removal of large series Rₜₕ of the sapphire substrate. After LLO, the mobility decreased from ≈1800 to ≈1500 cm²/Vs due to the introduction of traps during transfer. Drain current droop attributed to self-heating in as-fabricated HEMTs on sapphire is significantly reduced after transfer onto copper heat sink.

The following discussion refers to material for the Raman mapping images of both GaN E₂ (High) and AlN E₂ (High) mode in the access regions of both as-fabricated and LLO HEMT structures; lattice constants a and c of different epitaxial films, as well as this sample before and after LLO determined by HRXRD measurements; room temperature Raman shifts vs corresponding residual stress change indicated by both E₂ (High) and A₁ (Lo) modes; and TLM measurement results and transfer characteristics before and after LLO.

FIGS. 6A-6D show the Raman mapping images of both GaN E₂ (High) and AlN E₂ (High) mode in the access regions of both as-fabricated and LLO HEMT structures. In particular, the figures illustrate GaN E₂ (High) Raman strain mapping as-fabricated (FIG. 6A), and in LLO GaN HEMT (FIG. 6B). Further, AlN E₂ (High) Raman strain mapping as-fabricated is shown in FIG. 6C, and as LLO GaN HEMT in FIG. 6D.

FIG. 7A shows the a and c lattice constants of different epitaxial films, as well as this sample before and after LLO determined by HRXRD measurements.^{[57]} The partial strain relaxation after LLO is also supported by the lattice constant positions in FIG. 7A. In FIG. 7A, showing lattice constant a vs lattice constant c, the values of lattice constants are indicated as triangle showing a small portion of the residual strain is relieved after LLO. FIG. 7B displays the room temperature Raman shift vs corresponding residual stress for both E₂ (High) and A₁ (Lo) modes. The wavenumbers of the GaN E₂ (High) before and after LLO are 571.3 cm⁻¹ and 568.5 cm⁻¹, respectively, while the wavenumbers of the GaN A₁ (Lo) before and after LLO are 736.8 cm⁻¹ and 734 cm⁻¹, respectively. The vertical interpolation of both modes shows a ˜0.8 GPa biaxial stress change after LLO.

FIGS. 8A and 8B show the TLM measurements before (FIG. 8A) and after (FIG. 8B) LLO with width, w=200 μm and contact spacing from 4-12 μm. For an as-fabricated device, the ohmic contact resistance is R_{C1}=0.66 Ω-mm, while it increased marginally to R_{C2}=0.73 Ω-mm after LLO, and the sheet resistance increased from ˜310 Ω/sq to ˜374 Ω/sq after LLO.

FIGS. 9A and 9B show the transfer characteristics of the Al_{0.26}Ga_{0.74}N/GaN HEMT before (FIG. 9A) and after (FIG. 9B) laser lift-off (LLO) at V_{DS}=8 V.

This written description uses examples to disclose the presently disclosed subject matter, including the best mode, and also to enable any person skilled in the art to practice the presently disclosed subject matter, including making and using any devices or systems and performing any incorporated methods. The patentable scope of the presently disclosed subject matter is defined by the claims and may include other examples that occur to those skilled in the art. Such other examples are intended to be within the scope of the claims if they include structural and/or step elements that do not differ from the literal language of the claims, or if they include equivalent structural and/or elements with insubstantial differences from the literal languages of the claims.

### REFERENCES

[1] M. Asif Khan, X. Hu, A. Tarakji, G. Simin, J. Yang, R. Gaska, and M. S. Shur, Appl. Phys. Lett. 77, 1339 (2000).
[2] G. Simin, A. Tarakji, X. Hu, A. Koudymov, J. Yang, M. A. Khan, M. S. Shur, and R. Gaska, Phys. Status Solidi Appl. Res. 188, 219 (2001).
[3] V. Kumar, W. Lu, R. Schwindt, A. Kuliev, G. Simin, J. Yang, M. A. Khan, and I. Adesida, IEEE Electron Device Lett. 23, 455 (2002).
[4] U. K. Mishra, P. Parikh, and Y. F. Wu, Proc. IEEE 90, 1022 (2002).
[5] X. Hu, J. Deng, N. Pala, R. Gaska, M. S. Shur, C. Q. Chen, J. Yang, G. Simin, M. A. Khan, J. C. Rojo, and L. J. Schowalter, Appl. Phys. Lett. 82, 1299 (2003).
[6] G. Simin, X. Hu, N. llinskaya, A. Kumar, A. Koudymov, J. Zhang, M. Asif Khan, R. Gaska, and M. S. Shur, Electron. Lett. 36, 2043 (2000).
[7] C. Lee, H. Wang, J. Yang, L. Witkowski, M. Muir, M. A. Khan, and P. Saunier, Electron. Lett. 38, 924 (2002).
[8] V. Kumar, W. Lu, F. A. Khan, R. Schwindt, A. Kuliev, G. Simin, J. Yang, M. Asif Khan, and I. Adesida, Electron. Lett. 38, 252 (2002).
[9] See https://www.infineon.com/cms/en/product/power/gan-hemt-galliunitride-transistor/ for more information on applications of AlGaN/GaN HEMTs in consumer electronics (accessed 7 Jul. 2021).
[10] See https://www.qorvo.com/products/discrete-transistors/gan-hemts for more information on applications of AlGaN/GaN HEMTs in consumer electronics (accessed 7 Jul. 2021).
[11] M. A. Fraga, M. Bosi, and M. Negri, Advanced Silicon Carbide Devices Process (InTech, 2015), Chap. 1.
[12] Y. Sun, S. Trieu, T. Yu, Z. Chen, S. Qi, P. Tian, J. Deng, X. Jin, and G. Zhang, Semicond. Sci. Technol. 26, 085008 (2011).
[13] S. Hwang, D. Morgan, A. Kesler, M. Lachab, B. Zhang, A. Heidari, H. Nazir, I. Ahmad, J. Dion, Q. Fareed, V. Adivarahan, M. Islam, and A. Khan, Appl. Phys. Express 4, 032102 (2011).
[14] H. Aoshima, K. Takeda, K. Takehara, S. Ito, M. Mori, M. lwaya, T. Takeuchi, S. Kamiyama, I. Akasaki, and H. Amano, Phys. Status Solidi 9, 753 (2012).
[15] M. Lachab, F. Asif, B. Zhang, I. Ahmad, A. Heidari, Q. Fareed, V. Adivarahan, and A. Khan, Solid State Electron. 89, 156 (2013).
[16] F. Asif, H. C. Chen, A. Coleman, M. Lachab, I. Ahmad, B. Zhang, Q. Fareed, V. Adivarahan, and A. Khan, Jpn. J. Appl. Phys., Part 1 52, 08JG14 (2013).
[17] H. K. Cho, O. Kr€uger, A. K€ulberg, J. Rass, U. Zeimer, T. Kolbe, A. Knauer, S. Einfeldt, M. Weyers, and M. Kneissl, Semicond. Sci. Technol. 32, 12LT01 (2017).
[18] S. Bornemann, N. Yulianto, H. Spende, Y. Herbani, J. D. Prades, H. S. Wasisto, and A. Waag, Adv. Eng. Mater. 22, 1901192 (2020).
[19] K. Kawasaki, C. Koike, Y. Aoyagi, and M. Takeuchi, Appl. Phys. Lett. 89, 261114 (2006).
[20] X. Wang, C.-F. Lo, L. Liu, C. V. Cuervo, R. Fan, S. J. Pearton, B. Gila, M. R. Johnson, L. Zhou, D. J. Smith, J. Kim, O. Laboutin, Y. Cao, and J. W. Johnson, J. Vac. Sci. Technol. B 30, 051209 (2012).
[21] J. Das, W. Ruythooren, R. Vandersmissen, J. Derluyn, M. Germain, and G. Borghs, Phys. Status Solidi 2, 2655 (2005).
[22] K. K. Leung, C. P. Chan, W. K. Fong, M. Pilkuhn, H. Schweizer, and C. Surya, J. Cryst. Growth 298, 840 (2007).
[23] C. P. Chan, K. K. Leung, M. Pilkuhn, C. Surya, T. M. Yue, G. Pang, and H. Schweizer, Phys. Status Solidi 204, 914 (2007).
[24] H. Ji, J. Das, M. Germain, and M. Kuball, Solid State Electron. 53, 526 (2009).
[25] T. S. Kang, X. T. Wang, C. F. Lo, F. Ren, S. J. Pearton, O. Laboutin, Y. Cao, J. W. Johnson, and J. Kim, J. Vac. Sci. Technol. B 30, 011203 (2012).
[26] F. Guo, Q. Wang, H. Xiao, L. Jiang, W. Li, C. Feng, X. Wang, and Z. Wang, Semicond. Sci. Technol. 35, 095024 (2020).
[27] J. Schulz-Harder, Microelectron. Reliab. 43, 359-365 (2003).
[28] S. Yin, K. J. Tseng, and J. Zhao, Appl. Therm. Eng. 52, 120 (2013).
[29] Z. Cheng, Y. R. Koh, A. Mamun, J. Shi, T. Bai, K. Huynh, L. Yates, Z. Liu, R. Li, E. Lee, M. E. Liao, Y. Wang, H. M. Yu, M. Kushimoto, T. Luo, M. S. Goorsky, P. E. Hopkins, H. Amano, A. Khan, and S. Graham, Phys. Rev. Mater. 4, 044602 (2020).
[30] Y. R. Koh, Z. Cheng, A. Mamun, M. S. Bin Hogue, Z. Liu, T. Bai, K. Hussain, M. E. Liao, R. Li, J. T. Gaskins, A. Girl, J. Tomko, J. L. Braun, M. Gaevski, E. Lee, L. Yates, M. S. Goorsky, T. Luo, A. Khan, S. Graham, and P. E. Hopkins, ACS Appl. Mater. Interfaces 12, 29443 (2020).
[31] Q. Zheng, C. Li, A. Rai, J. H. Leach, D. A. Broido, and D. G. Cahill, Phys. Rev. Mater. 3, 014601 (2019).
[32] H. Shibata, Y. Waseda, H. Ohta, K. Kiyomi, K. Shimoyama, K. Fujito, H. Nagaoka, Y. Kagamitani, R. Simura, and T. Fukuda, Mater. Trans. 48, 2782 (2007).
33 A. Jezowski, B. A. Danilchenko, M. Boc′kowski, I. Grzegory, S. Krukowski, T. Suski, and T. Paszkiewicz, Solid State Commun. 128, 69 (2003).
[34] S. Mollah, K. Hussain, A. Mamun, M. Gaevski, G. Simin, M. V. S. Chandrashekhar, and A. Khan, Appl. Phys. Express 14, 014003 (2021).
[35] M. Gaevski, S. Mollah, K. Hussain, J. Letton, A. Mamun, M. U. Jewel, M. Chandrashekhar, G. Simin, and A. Khan, Appl. Phys. Express 13, 094002 (2020).
[36] H. Xue, K. Hussain, V. Talesara, T. Razzak, M. Gaevski, S. Mollah, S. Rajan, A. Khan, and W. Lu, Phys. Status Solidi 15, 2000576 (2021).
[37] S. A. Vitusevich, A. M. Kurakin, N. Klein, M. V. Petrychuk, A. V. Naumov, and A. E. Belyaev, IEEE Trans. Device Mater. Reliab. 8, 543 (2008).
[38] Z. Y. Fan, J. Li, J. Y. Lin, and H. X. Jiang, Appl. Phys. Lett. 81, 4649 (2002).
[39] See https://www.indium.com/bLog/indium-lead-inpb-solder-alLoys-for-reliablegold-interconnects-in-semiconductor-assembly.php for more information on melting temperature of In—Pb solder; accessed 7 Jul. 2021.
[40] M. Kuball, Surf. Interface Anal. 31, 987 (2001).
[41] Y. Huang, X. D. Chen, S. Fung, C. D. Beling, and C. C. Ling, J. Phys. D: Appl. Phys. 37, 2814 (2004).
[42] S. Choi, E. Heller, D. Dorsey, R. Vetury, and S. Graham, J. Appl. Phys. 113, 093510 (2013).
[43] S. Chae, K. A. Mengle, R. Lu, A. Olvera, N. Sanders, J. Lee, P. F. P. Poudeu, J. T. Heron, and E. Kioupakis, Appl. Phys. Lett. 117, 102106 (2020).
[44] R. Gaska, A. Osinsky, J. W. Yang, and M. S. Shur, IEEE Electron Device Lett. 19, 89 (1998).
[45] M. Kuball, J. W. Pomeroy, R. Simms, G. J. Riedel, H. Ji, A. Sarua, M. J. Uren, and T. Martin, in IEEE Compound Semiconductor Integrated Circuit Symposium, Technical Digest (IEEE, 2007), Vol. 116.
[46] M. Kuball, J. M. Hayes, M. J. Uren, T. Martin, J. C. H. Birbeck, R. S. Balmer, and B. T. Hughes, IEEE Electron Device Lett. 23, 7 (2002).
[47] J. Sun, H. Fatima, A. Koudymov, A. Chitnis, X. Hu, H. M. Wang, J. Zhang, G. Simin, J. Yang, and M. A. Khan, IEEE Electron Device Lett. 24, 375 (2003).
[48] J. G. Felbinger, M. V. S. Chandra, Y. Sun, L. F. Eastman, J. Wasserbauer, F. Faili, D. Babic, D. Francis, and F. Ejeckam, IEEE Electron Device Lett. 28, 948 (2007).
[49] See https://www.indium.com/applications/thermal-management/#thermal-kvalues-list for more information on thermal conductivity of In—Pb solder; accessed 7 Jul. 2021.
[50] See http://hyperphysics.phy-ast.gsu.edu/hbase/Tables/thrcn.html for more information on thermal conductivity of copper; accessed 7 Jul. 2021.
[51] F. Roccaforte, G. Greco, P. Fiorenza, and F. Iucolano, Materials 12, 1599 (2019).
[52] M. Chu, A. D. Koehler, A. Gupta, S. Parthasarathy, M. O. Baykan, S. E. Thompson, and T. Nishida, Materials and Reliability Handbook for Semiconductor Optical and Electron Devices (Springer, 2013), Vol. 381.
[53] B. Shankar, A. Soni, S. Raghavan, and M. Shrivastava, IEEE Trans. Device Mater. Reliab. 20, 767 (2020).
[54] T. Beechem, A. Christensen, D. S. Green, and S. Graham, J. Appl. Phys. 106, 114509 (2009).
[55] J. A. del Alamo and J. Joh, Microelectron. Reliab. 49, 1200 (2009).
[56] See https://www.tepella.com/technote_html/16047-TN-V1-06232009.pdf for more information on thermal conductivity of silver paint; accessed 7 Jul. 2021.
[57] S. Choi, E. Heller, D. Dorsey, R. Vetury, and S. Graham, J. Appl. Phys. 113, 093510 (2013).
[58] M. Kuball et al., “Thermal properties and reliability of GaN microelectronics: Sub-micron spatial and nanosecond time resolution thermography,” Tech. Dig.—IEEE Compd.
[59] S. Karrakchou et al., “Effectiveness of selective area growth using van der Waals h-BN layer for crack- free transfer of large-size III-N devices onto arbitrary substrates,” Sci. Reports 2020 101, vol. 10, no. 1, pp. 1-9, December 2020.
[60] T. Ayari et al., “Novel Scalable Transfer Approach for Discrete III-Nitride Devices Using Wafer-Scale Patterned h-BN/Sapphire Substrate for Pick-and-Place Applications,” Adv. Mater. Technol., vol. 4, no. 10, p. 1900164, October 2019.
[61] S. Sundaram et al., “MOVPE of GaN-based mixed dimensional heterostructures on wafer-scale layered 2D hexagonal boron nitride—A key enabler of III-nitride flexible optoelectronics,” APL Mater., vol. 9, no. 6, p. 061101, June 2021.
[62] Y. Kobayashi, K. Kumakura, T. Akasaka, and T. Makimoto, “Layered boron nitride as a release layer for mechanical transfer of GaN-based devices,” Nat. 2012 4847393, vol. 484, no. 7393, pp. 223-227, April 2012.
[63] L. F. Wang et al., “Novel Design of SOI SiGe HBTs with High Johnson's Figure-of-Merit,” 2018 IEEE 3rd Int. Conf. Integr. Circuits Microsystems, ICICM 2018, pp. 56-59, December 2018.
[64] I. S. M. Sun et al., “Novel ultra-Low power RF lateral BJT on SOI-CMOS compatible substrate,” 2005 IEEE Conf. Electron Devices Solid-State Circuits, EDSSC, pp. 317-320, 2005.
[65] S. Lee et al., “Record RF performance of 45-nm SOI CMOS technoLogy,” Tech. Dig.—Int. Electron Devices Meet. IEDM, pp. 255-258, 2007.

What is claimed is:

1. A method for transferring wide and ultrawide bandgap (WBG and UWBG) layers to an engineered substrate, comprising:
performing laser-based lift-off (LLO) on high-electron mobility transistors (HEMTs) with AlN heat spreading buffer layers grown over sapphire substrate material, to remove the sapphire substrate material; and
applying a carrier substrate to the heat spreading buffer layers using a bonding agent, to collectively form an engineered substrate.

2. The method according to claim 1, wherein:
the HEMTs comprise AlGaN/GaN HEMTs;
the laser-based lift-off (LLO) includes use of an excimer laser having a wavelength of less than 250 nm; and
the AlN heat spreading buffer layers are at least 10 μm thick.

3. The method according to claim 2, wherein:
the HEMTs comprise Al_{0.26}Ga_{0.74}N/GaN high-electron mobility transistors;
the laser-based lift-off (LLO) includes use of a 193-nm excimer laser; and
the AlN heat spreading buffer layers are about 16 μm thick.

4. The method according to claim 1, wherein the carrier substrate comprises a heat sink layer.

5. The method according to claim 4, where the heat sink layer comprises copper and the bonding agent comprises solder.

6. The method according to claim 1, wherein the laser-based lift-off (LLO) includes using an ultraviolet laser light passed through the sapphire substrate material to ablate an interface with the sapphire substrate material to release the sapphire substrate material.

7. An engineered substrate made according to the method of claim 1.

8. A double transfer method for fabricating WBG and UWBG semiconductor devices without requiring a final polishing step, comprising:
forming AlGaN/GaN HEMTs on a layer of AlN heat spreaders having a thickness of at least 10 μm, grown over sapphire substrate materials;
applying excimer laser lift-off to remove the sapphire substrate materials to expose the layer of AlN heat spreaders; and
using a bonding agent to apply a heat sink layer to the exposed layer of AlN heat spreaders;
whereby first transferring off the sapphire substrate materials and subsequently transferring on a heat sink layer results in engineered formation of WBG and UWBG power devices.

9. The method according to claim 8, further comprising:
before applying excimer laser lift-off, bonding UV tape to a side of the HEMT opposite the sapphire substrate materials; and
after applying a heat sink layer to the exposed layer of AlN heat spreaders, removing the UV bonding tape.

10. The method according to claim 8, further comprising, after applying excimer laser lift-off to remove the sapphire substrate materials, cleaning the exposed layer of AlN heat spreaders.

11. The method according to claim 10, wherein the cleaning comprises cleaning with 1:1 dilute HCl and Cl₂/Ar ICP.

12. The method according to claim 10, wherein applying a heat sink layer to the exposed layer of AlN heat spreaders comprises bonding the exposed layer of AlN heat spreaders to a copper heat sink substrate using In—Pb solder by thermocompression bonding

13. A semiconductor device made according to the method of claim 8.

14. Methodology for forming a layered substrate, comprising:
performing laser-based lift-off (LLO) on AlGaN high-electron mobility transistors (HEMTs) with ceramic heat spreading buffer layers having relatively high thermal conductivity, and grown over sapphire substrate material, to remove the sapphire substrate material; and
applying a copper heat sink to the ceramic heat spreading buffer layers using a bonding agent, to collectively form an engineered layered substrate.

15. The methodology according to claim 14, wherein the ceramic heat spreading buffer layers comprise aluminum nitride (AlN).

16. The methodology according to claim 14, wherein the ceramic heat spreading buffer layers comprise III nitride material.

17. The methodology according to claim 14, wherein:
the AlGaN high-electron mobility transistors (HEMTs) comprise ultrawide bandgap (UWBG) AlGaN HEMTs; and
the ceramic heat spreading buffer layers comprise aluminum nitride (AlN) having a thickness of at least 10 μm.

18. The methodology according to claim 17, wherein the laser-based lift-off (LLO) is performed on Al_{0.26}Ga_{0.74}N/GaN HEMT by a 193-nm ArF excimer laser and transferred onto a copper heat sink bonded by In—Pb solder.

19. A layered substrate made according to the methodology of claim 14.
